(19) United States
(12) Patent Application Publication
(10) Pub. No.: US 2009/0039519 A1
(43) Pub. Date: Feb. 12, 2009

(54) SEMICONDUCTOR DEVICE, PHOTOMASK, SEMICONDUCTOR DEVICE PRODUCTION METHOD, AND PATTERN LAYOUT METHOD

(75) Inventors: Takayuki Saito, Tokyo (JP); Takeo Ishibashi, Tokyo (JP); Itaru Kanai, Tokyo (JP)

Correspondence Address: MCDERMOTT WILL & EMERY LLP, 600 13TH STREET, N.W., WASHINGTON, DC, 20005-3096, US

(73) Assignees: RENESAS TECHNOLOGY CORP.; POWERCHIP SEMICONDUCTOR CORP.

(21) Appl. No.: 12/187,786

(22) Filed: Aug. 7, 2008

(30) Foreign Application Priority Data
Aug. 10, 2007 (JP) 2007-209887

(51) Int. Cl. H01L 23/48; G03F 1/00

(52) U.S. Cl. 257/773; 430/5; 430/319; 257/E23.01

(57) ABSTRACT

A semiconductor device according to an aspect of the invention includes plural line pattern and plural pad patterns. The line patterns are repeatedly disposed with a space pattern interposed therebetween. The pad pattern straddles plural columns of the line patterns. The pad pattern is connected to the line pattern located on one side of the pad pattern in one of the plural columns, the pad pattern is connected to the line pattern located on the other side of the pad pattern in another column of the plural columns, and the line pattern located on one side of the pad pattern includes an open-circuit portion in another column. Therefore, a semiconductor device in which an interconnection pattern including the fine line-and-space-shape line pattern and the pad pattern is accurately formed at low cost, a semiconductor device production method, and a photomask used to produce the semiconductor device can be provided.

### BACKGROUND OF THE INVENTION

1. Field of the Invention

The present invention relates to a semiconductor device having a line pattern and a pad pattern, a photomask used to produce the semiconductor device, a semiconductor device production method in which the photomask is used, and a pattern layout method for performing a pattern layout of the photomask.

2. Description of the Background Art

In an interconnection pattern of a semiconductor device, for example, a gate pattern of a flash memory includes a line pattern and a pad pattern. In the line pattern, line patterns and space patterns are repeatedly disposed so as to form a line and space (L/S) shape. The pad pattern is used to establish electrical contact with the line pattern through a contact hole.

In the case where a fine process is required like a memory cell portion of a semiconductor memory device, sometimes exposure is performed with off axis illumination such as dipole illumination to improve resolution in a photolithographic process for an interconnection pattern shape. The off axis illumination enables two-beam interference exposure in which zero-order diffraction light and first-order diffraction light are used, thereby obtaining the fine L/S pattern. Desirably L/S regularity of the exposure pattern does not collapse as much as possible in order to ensure exposure accuracy. However, usually the interconnection pattern has the pad pattern wider than the line pattern, and the L/S regularity of the interconnection pattern collapses. In the case of the large collapse, sometimes a short circuit between the line pattern and the pad pattern or an open circuit of the line pattern is generated contrary to design.

For example, Japanese Patent Laying-Open No. 2006-128255 discloses a double exposure technique in order to perform the exposure with the high L/S regularity. In the technique disclosed in Japanese Patent Laying-Open No. 2006-128255, an L/S-shape line pattern portion is exposed independently of the pad pattern (connecting pattern) portion in the interconnection pattern. Therefore, the L/S regularity becomes high during the exposure, and the exposure can be performed with high accuracy.

In the technique disclosed in Japanese Patent Laying-Open No. 2006-128255, because the exposure process is performed twice, throughput of the exposure process is lowered, and two photomasks are required to increase cost.

In the case where a pad pattern PD provided in each of a plurality of line patterns LN is disposed on the identical end portion side (left side in FIG. 9) in a direction in which line patterns LN are extended like an interconnection pattern WP1C of FIG. 9, it is difficult that pad pattern PD is accurately aligned with line pattern LN in the double exposure process.

### SUMMARY OF THE INVENTION

In view of the foregoing, an object of the invention is to provide a semiconductor device in which the interconnection pattern having the fine L/S-shape line pattern and the pad pattern is accurately formed at low cost, a semiconductor device production method, and a photomask used to produce the semiconductor device.

Another object of the invention is to provide a pattern layout method for being able to easily perform a pattern layout of the photomask which is used to accurately form the interconnection pattern having the fine L/S-shape line pattern and the pad pattern at low cost.

A semiconductor device according to an embodiment of the present invention includes a plurality of line patterns, and a straddling pattern. The line patterns are repeatedly disposed with a space pattern interposed therebetween. The straddling pattern straddles a plurality of columns of the line patterns. The straddling pattern is connected to the line pattern located on one side of the straddling pattern in one of the plurality of columns, the straddling pattern is connected to the line pattern located on the other side of the straddling pattern in another column of the plurality of columns, and the line pattern located on one side of the straddling pattern includes an open-circuit portion in another column.

A photomask according to the embodiment of the present invention includes a plurality of line patterns, and a straddling pattern. The line patterns are repeatedly disposed with a space pattern interposed therebetween. The straddling pattern straddles a plurality of columns of the line patterns. The straddling pattern is connected to the line pattern located on one side of the straddling pattern in one of the plurality of columns. The straddling pattern is connected to the line pattern located on the other side of the straddling pattern in another column of the plurality of columns. The line pattern located on one side of the straddling pattern includes an open-circuit portion in another column.

A pattern layout method according to the embodiment of the present invention for performing a pattern layout of a photomask, the method includes following steps.

Optical proximity correction is performed to a first pattern shape, the first pattern shape including a plurality of line pattern shapes which run parallel to one another with a space pattern interposed therebetween, a pattern shape which straddles the plurality of line pattern shapes, and a set of line pattern shapes which runs parallel to the plurality of line pattern shapes, the straddling pattern shape being sandwiched between the set of line pattern shapes with a space pattern interposed therebetween. Optical proximity correction is performed to a second pattern shape, the second pattern shape including a line pattern shape which has an open-circuit portion and a set of line pattern shapes which runs parallel to the line pattern shapes having the open-circuit portion, the open-circuit portion being sandwiched between the set of line pattern shapes with a space pattern interposed therebetween. One of regions and another region in a pattern shape are respectively replaced by the first and second pattern shapes to which the optical proximity correction is already performed, the pattern shape including a plurality of line pattern shapes which are repeatedly disposed with a space pattern interposed therebetween.

Accordingly, the exposure process is collectively performed using the patter having high L/S regularity in the photolithography of the interconnection pattern including the fine L/S-shape line pattern and the pad pattern. Therefore, the line pattern and pad pattern of the semiconductor device can accurately be formed at low cost.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view showing a schematic configuration of an interconnection pattern in a semiconductor device according to a first embodiment of the invention.

FIG. 2 is an enlarged view of a broken-line portion II of FIG. 1.

FIG. 3 is a plan view schematically showing a short-circuit pattern shape used in a pattern layout method of the first embodiment.

FIG. 4 is a plan view schematically showing a short-circuit pattern shape used in the pattern layout method of the first embodiment.

FIG. 5 is a plan view schematically showing a short-circuit pattern shape used in the pattern layout method of the first embodiment.

FIG. 6 is a plan view showing a schematic configuration of a photomask of the first embodiment.

FIG. 7 is a sectional view for schematically describing a semiconductor device production method of the first embodiment.

FIG. 8 is a plan view showing a schematic configuration of a light-shielding plate of a projection type exposure instrument used in the semiconductor device production method of the first embodiment.

FIG. 9 is a plan view showing a schematic configuration of an interconnection pattern of a semiconductor device according to Comparative Example.

FIG. 10 is an enlarged view of a broken-line portion X of FIG. 9.

FIG. 11 is a plan view schematically showing a short-circuit pattern shape, in which optical proximity correction is performed, used in a pattern layout method according to a second embodiment of the invention.

FIG. 12 is a plan view schematically showing a short-circuit pattern shape, in which the optical proximity correction is performed, used in the pattern layout method of the second embodiment.

FIG. 13 is a plan view showing a schematic configuration of a photomask of the second embodiment.

FIG. 14 is a partial plan view showing a schematic configuration around a pad pattern in an interconnection pattern of a semiconductor device of the second embodiment.

FIG. 15 is a partial plan view showing a schematic configuration around an open-circuit portion in the interconnection pattern of the semiconductor device of the second embodiment.

FIG. 16 is a partial plan view showing a schematic configuration of the interconnection pattern of the semiconductor device of the second embodiment.

FIG. 17 is a plan view showing a schematic configuration of an interconnection pattern of a semiconductor device according to a third embodiment of the invention.

FIG. 18 is an enlarged view of a broken-line portion XVIII of FIG. 17.

FIG. 19 is a plan view schematically showing a basic pattern shape used in a pattern layout method of the third embodiment.

FIG. 20 is a plan view showing a schematic configuration of a photomask of the third embodiment.

FIG. 21 is a partial plan view showing a schematic configuration of an interconnection pattern of a semiconductor device according to Comparative Example.

FIG. 22 is a plan view showing a schematic configuration of a photomask according to a fourth embodiment of the invention.

FIG. 23 is a partial plan view showing a schematic configuration of an interconnection pattern of a semiconductor device of the fourth embodiment.

FIG. 24 is a plan view schematically showing a gate interconnection of a semiconductor device according to a fifth embodiment of the invention.

FIG. 25 is a plan view schematically showing a first metal interconnection of the semiconductor device of the fifth embodiment.

FIG. 26 is a plan view schematically showing a layout of contact holes made in the first metal interconnection of the semiconductor device of the fifth embodiment.

FIG. 27 is a plan view schematically showing a second metal interconnection of the semiconductor device of the fifth embodiment.

FIG. 28 is a schematic sectional view taken on a line XXVIII-XXVIII of FIGS. 24 to 27.

FIG. 29 is a schematic sectional view taken on a line XXIX-XXIX of FIGS. 24 to 27.

### DESCRIPTION OF THE PREFERRED EMBODIMENTS

Exemplary embodiments of the invention will be described below with reference to the drawings.

### First Embodiment

A configuration of an interconnection pattern in a semiconductor device according to a first embodiment of the invention will be described.

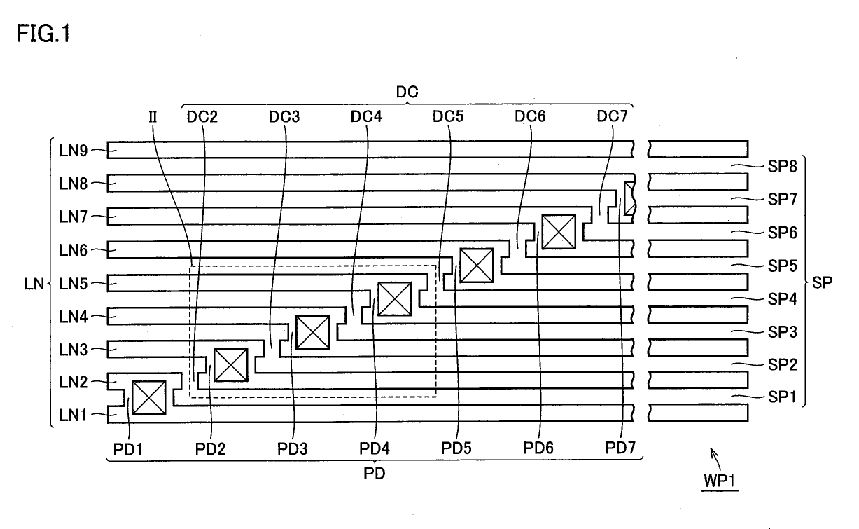

Referring to FIG. 1, an interconnection pattern WP1 of the first embodiment includes a plurality of line patterns LN (LN1 to LN9) and a plurality of pad patterns (straddling pattern) PD (PD1 to PD7). Line patterns LN are repeatedly disposed with a space pattern SP (SP1 to SP8) interposed therebetween. Pad pattern PD is disposed while straddling a plurality of columns of line patterns LN. Each of line patterns LN2 to LN7 includes each (open-circuit portion DC) of open-circuit portions DC2 to DC7. In FIG. 1, an X-letter appended square located near the center of each pad pattern PD indicates a position of a contact hole made in pad pattern PD.

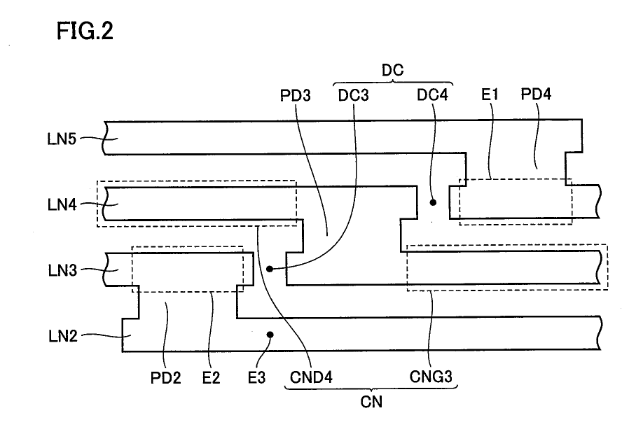

Referring to FIG. 2, pad pattern PD3 is disposed while straddling a plurality of columns of line patterns LN3 and LN4. In one (column of line pattern LN3) of the plurality of columns, pad pattern PD3 is connected to line pattern LN3 (interconnection CNG3) located on one side (right side in FIG. 2) of pad pattern PD3. In the other column (column of line pattern LN4) of the plurality of columns, pad pattern PD3 is connected to line pattern LN4 (interconnection CND4) located on the other side (left side in FIG. 2) of pad pattern PD3.

In pad pattern PD3, line pattern LN4 located on one side (right side in FIG. 2) of pad pattern PD3 includes open-circuit portion DC4 in the other column (column of line pattern LN4) of the plurality of columns. Line pattern LN3 located on the other side (left side in FIG. 2) of pad pattern PD3 includes open-circuit portion DC3 in one (column of line pattern LN3) of the plurality of columns.

Line patterns LN3 and LN4 connected to pad pattern PD3 and each of open-circuit portions DC3 and DC4 included in each of line patterns LN3 and LN4 are described above by way of example. In addition to pad pattern PD3, as shown in FIG. 1, other pad patterns PD are also connected to line pattern LN, and the connected line pattern LN include open-circuit portions DC. Because the relationship among pad pattern PD, line pattern LN, and open-circuit portion DC included in line pattern LN is similar to that of pad pattern PD3, the description thereof is not given.

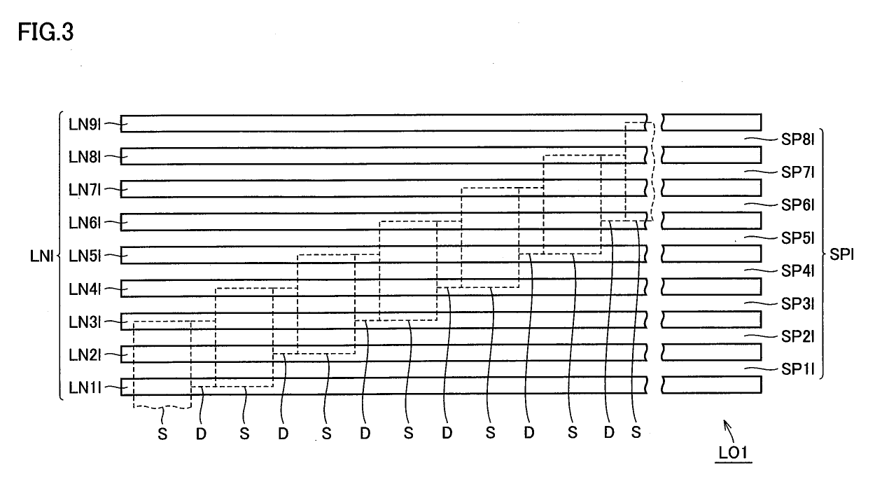

A pattern layout method for performing a pattern layout of a photomask of the first embodiment will be described. Mainly referring to FIG. 3, a basic pattern shape LO1 includes a plurality of line pattern shapes LN1 (LN1l to LN9l) which are repeatedly disposed with space pattern SP1 (SP1l to SP8l) interposed therebetween. A plurality of line pattern shapes LN1 have the same length, and line pattern shapes LN1 are arrayed along an L/S periodic direction. Each of line pattern shapes LN1 and space pattern shapes SP1 has a width (size in the L/S periodic direction) of 65 nm.

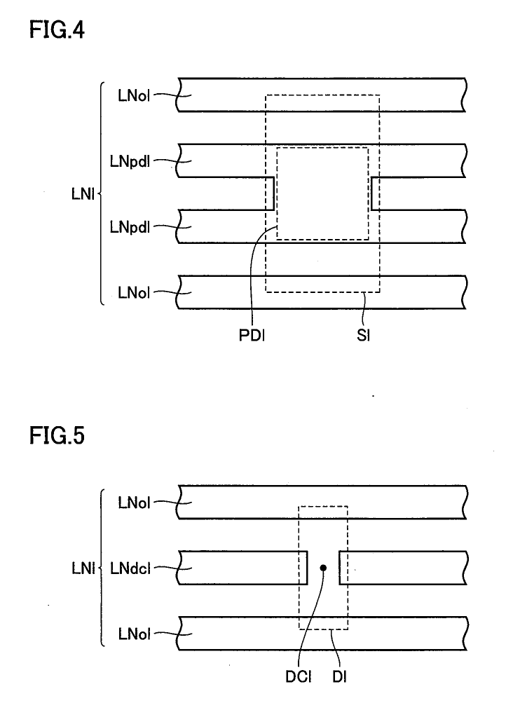

A short-circuit region (one of regions) S and an open-circuit region (the other region) D in basic pattern shape LO1 are replaced by a short-circuit pattern shape (first pattern shape) Sl (FIG. 4) and an open-circuit pattern shape (second pattern shape) Dl (FIG. 5) respectively. Therefore, the pattern layout of the photomask is performed.

As shown in FIG. 4, short-circuit pattern shape Sl includes a plurality of line pattern shapes LNpdl which run parallel to one another with a space pattern interposed therebetween, a pad pattern shape PD1 straddling a plurality of line pattern shapes LNpdl, and a set of line pattern shapes LNol. The set of line pattern shapes LNol runs parallel to a plurality of line pattern shapes LNpdl, and pad pattern shape PD1 is sandwiched between line pattern shapes LNol while a space pattern is interposed between pad pattern shape PD1 and line pattern shapes LNol. For example, pad pattern shape PD1 has a length (size in a direction in which line pattern shape LN1 is extended) of 180 nm.

As shown in FIG. 5, open-circuit pattern shape Dl includes line pattern shape LNdcl and the set of line pattern shapes LNol. Line pattern shape LNdcl includes an open-circuit portion DC1. The set of line pattern shapes LNol runs parallel to line pattern shape LNdcl, and open-circuit portion DC1 is sandwiched between line pattern shapes LNol while a space pattern is interposed between open-circuit portion DC1 and line pattern shapes LNol.

Each broken-line portion corresponds to a region (short-circuit region S or open-circuit region D) where basic pattern shape LO1 are replaced in the pattern layout.

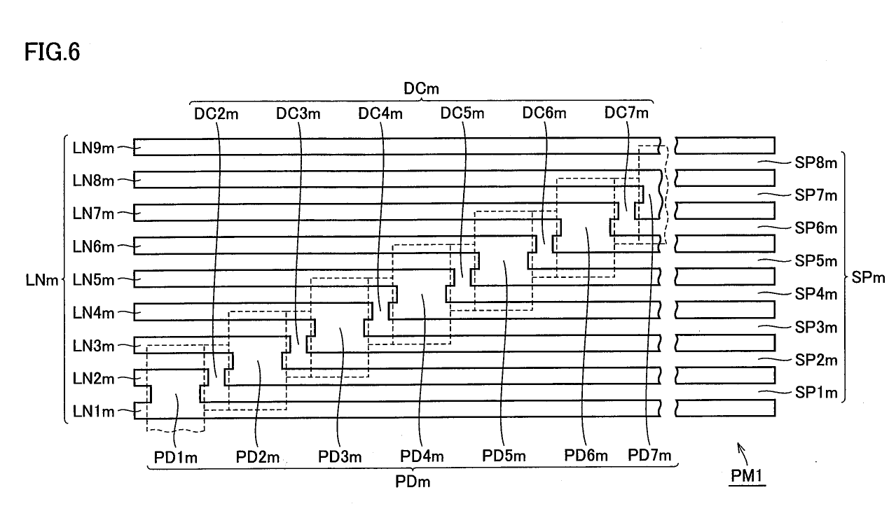

Referring to FIG. 6, a photomask PM1 of the first embodiment includes a plurality of line patterns LNm (LN1m to LN9m) and a plurality of pad patterns (straddling pattern) PDm (PD1m to PD7m). Line patterns LNm are repeatedly disposed with a space pattern SPm (SP1m to SP8m) interposed therebetween. Pad pattern PDm is disposed while straddling a plurality of columns of line patterns LNm. Each of line patterns LN2m to LN7m includes each (open-circuit portion DCm) of open-circuit portions DC2m to DC7m.

For example, pad pattern PD3m is disposed while straddling a plurality of columns of line patterns LN3m and LN4m. In one (column of line pattern LN3m) of the plurality of columns, pad pattern PD3m is connected to line pattern LN3m located on one side (right side in FIG. 6) of pad pattern PD3m. In the other column (column of line pattern LN4m) of the plurality of columns, pad pattern PD3m is connected to line pattern LN4m located on the other side (left side in FIG. 6) of pad pattern PD3m. In pad pattern PD3m, line pattern LN4m located on one side (right side in FIG. 6) of pad pattern PD3m includes open-circuit portion DC4m in the other column (column of line pattern LN4m) of the plurality of columns. Line pattern LN3m located on the other side (left side in FIG. 6) of pad pattern PD3m includes open-circuit portion DC3m in one (column of line pattern LN3m) of the plurality of columns.

Line patterns LN3m and LN4m connected to pad pattern PD3m and each of open-circuit portions DC3m and DC4m included in each of line patterns LN3m and LN4m are described above by way of example. In addition to pad pattern PD3m, other pad patterns PDm are also connected to line patterns LNm, and the connected line patterns LNm include open-circuit portions DCm. Because the relationship among pad pattern PDm, line pattern LNm, and open-circuit portion DCm included in line pattern LNm is similar to that of pad pattern PD3m, the description thereof is not given.

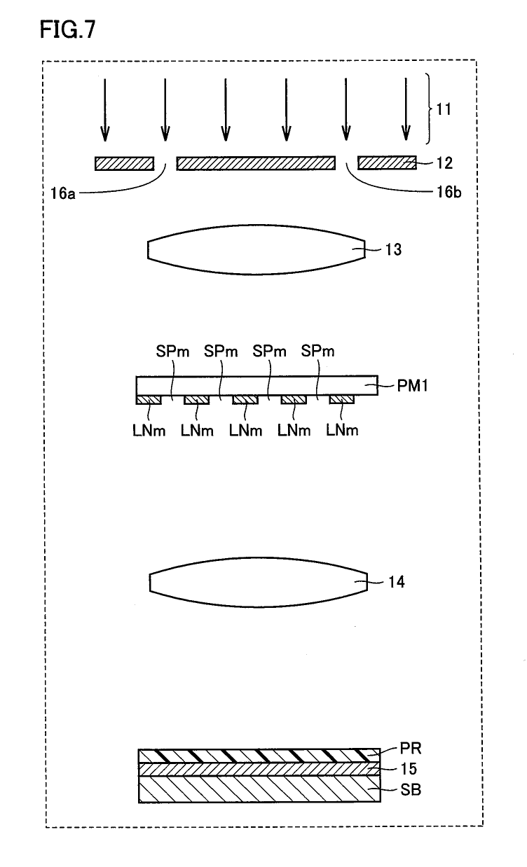

A semiconductor device production method in which the photomask of the first embodiment is used will be described below. Mainly referring to FIG. 7, a conductive layer 15 is deposited on a semiconductor substrate SB. Then, a photoresist PR is applied thereto.

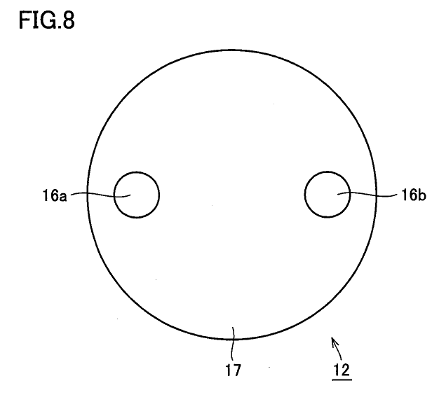

As shown in a broken line of FIG. 7, photoresist PR is exposed with a projection type exposure instrument. In order to perform off axis illumination, the projection type exposure instrument includes a light source which emits light 11, a light-shielding plate 12, a condenser lens 13, and a reduction projection lens 14. As shown in FIG. 8, light-shielding plate 12 includes a light-shielding portion 17 and two translucent portions 16a and 16b.

A photomask PM1 is attached between light-shielding plate 12 and reduction projection lens 14. In the attachment, a direction in which two translucent portions 16a and 16b of light-shielding plate 12 faces each other is aligned with a periodic direction (direction orthogonal to the direction in which each line pattern LNm is extended) in which line patterns LNm of photomask PM1 are repeatedly disposed.

Light 11 is sequentially transmitted through light-shielding plate 12, condenser lens 13, photomask PM, and reduction projection lens 14, and reaches a photoresist PR. Accordingly, photoresist PR is exposed with the off axis illumination. Then, photoresist PR is developed to transfer a pattern shape of photomask PM1 to photoresist PR.

Then, conductive layer 15 is etched while photoresist PR is used as a mask. Then, photoresist PR is removed. Therefore, interconnection pattern WP1 (FIG. 1) is formed from conductive layer 15. An insulating layer (not shown) is formed on interconnection pattern WP1. Then, the contact hole is made in the insulating layer. Thus, the semiconductor device having interconnection pattern WP1 (FIG. 1) is obtained.

In the first embodiment, as shown in FIG. 2, interconnection CNG3 is connected to pad pattern PD3, so that interconnection CNG3 can be used as a gate interconnection of the semiconductor device. As shown in FIG. 1, for the other pad patterns PD, line pattern LN connected onto one side (right side in FIG. 1) of pad pattern PD can be used as the gate interconnection and the like. That is, the layout in which the gate interconnection is formed on one side (right side in FIG. 1) of pad pattern PD can be obtained in the first embodiment. Therefore, pad pattern PD can unevenly be provided on the other side (left side in FIG. 1) of the interconnection such as the gate interconnection.

As shown in FIG. 2, pad pattern PD3 straddles the column of line pattern LN4, and a partial region E1 of pad pattern PD4 is also located in the column of line pattern LN4. Pad patterns PD3 and PD4 are electrically separated from each other by the existence of open-circuit portion DC4.

Pad pattern PD3 also straddles the column of line pattern LN3, and a partial region E2 of pad pattern PD2 is also located in the column of line pattern LN3. Pad patterns PD2 and PD3 are electrically separated from each other by the existence of open-circuit portion DC3.

Pad pattern PD3 is connected to interconnection CND4 located on the other side (left side in FIG. 2) of the column of line pattern LN4. Therefore, interconnection CND4 is formed at a position shifted from a position E3 of interconnection LN2 by two columns. That is, the L/S regularity is enhanced in position E3 when compared to the absence of interconnection CND4. Therefore, the exposure process can more accurately be performed in position E3.

A total length of line patterns LN connected to pad pattern PD3 is the sum of a length of line pattern LN3 (interconnection CNG3) in one of columns (column of LN3 in FIG. 2) connected onto one side (right side in FIG. 2) of pad pattern PD3 and a length of line pattern LN4 (interconnection CNG4) in the other column (column of LN4 in FIG. 2) connected onto the other side (left side in FIG. 2). Referring to FIG. 1, the total length is kept constant for each pad pattern PD. Accordingly, an interconnection capacitance can be kept constant in the interconnection pattern to which each of a plurality of pad patterns PD is connected.

As shown in FIG. 7, because the off axis illumination is used for photomask PM1 having the high L/S regularity, an exposure accuracy improving effect can be further strengthened by the off axis illumination.

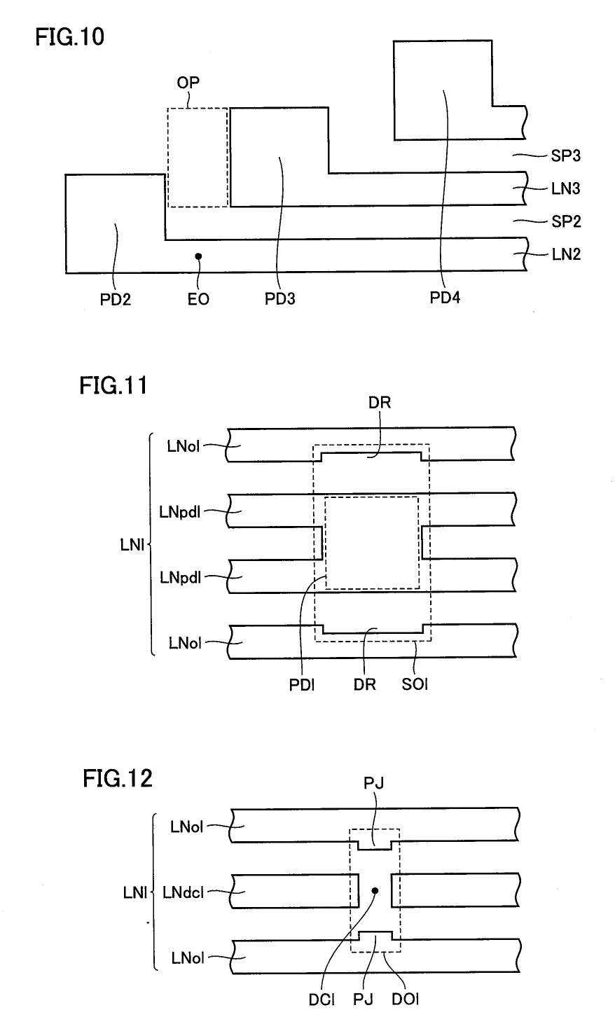

As shown in FIG. 10, in Comparative Example, contrary to the L/S regularity, a region OP where the line pattern is not formed is enlarged on the other side (left side in FIG. 10) of pad pattern PD3. Accordingly, the accuracy of exposure process is lowered, and a possibility of opening a position EO of line pattern LN2 is enhanced contrary to the electric design of the semiconductor device.

Pad patterns PD2 and PD3 are electrically separated by region OP. Region OP is located between pad patterns PD2 and PD3. That is, region OP is a portion which is directly sandwiched by patterns which are wider than line pattern LN, and the accuracy of exposure process is lowered to enhance a possibility of generating a short circuit.

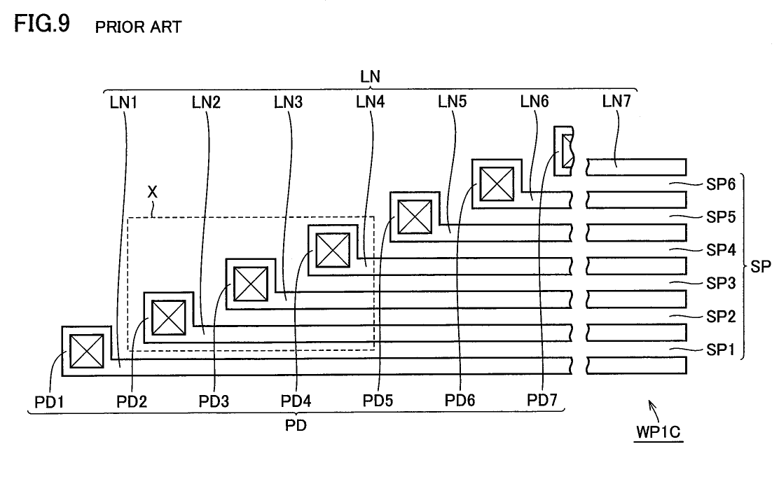

As shown in FIG. 9, in Comparative Example 9, line pattern LN2 connected to pad pattern PD2 is longer than line pattern LN3 connected to pad pattern PD3. Accordingly, in Comparative Example, a variation in interconnection capacitance is enlarged in the interconnection pattern to which each of a plurality of pad patterns PD is connected.

### Second Embodiment

A pattern layout method for performing a pattern layout of a photomask used to produce a semiconductor device according to a second embodiment of the invention will be described.

Mainly referring to FIG. 11, optical proximity correction is performed to short-circuit pattern shape Sl (FIG. 4) of the first embodiment. Therefore, a short-circuit pattern shape SO1 to which the optical proximity correction is already performed is obtained. In the set of line pattern shape LNol, through the optical proximity correction, a recess DR is provided in a portion which faces pad pattern shape PD1 with a space pattern interposed therebetween. A width of line pattern shape LNol is narrowed only by 15 nm in recess DR.

Mainly referring to FIG. 12, the optical proximity correction is performed to open-circuit pattern shape Dl (FIG. 5) of the first embodiment. Therefore, an open-circuit pattern shape DO1 to which the optical proximity correction is already performed is obtained. In the set of line pattern shape LNol, through the optical proximity correction, a protrusion PJ is provided in a portion which faces open-circuit portion DC1 with a space pattern interposed therebetween. A width of line pattern shape LNol is widened only by 15 nm in protrusion PJ.

Then, short-circuit region (one of regions) S and open-circuit region (the other region) D in basic pattern shape LO1 (FIG. 3) are replaced by short-circuit pattern shape SO1 (FIG. 11) to which the optical proximity correction is already performed and open-circuit pattern shape DO1 (FIG. 12) to which the optical proximity correction is already performed respectively. Therefore, the pattern layout of the photomask is performed.

The photomask obtained by the pattern layout method will be described. Each of the broken-line portions corresponds to the region (short-circuit region S or open-circuit region D) where basic pattern shape LO1 (FIG. 3) is replaced in the pattern layout.

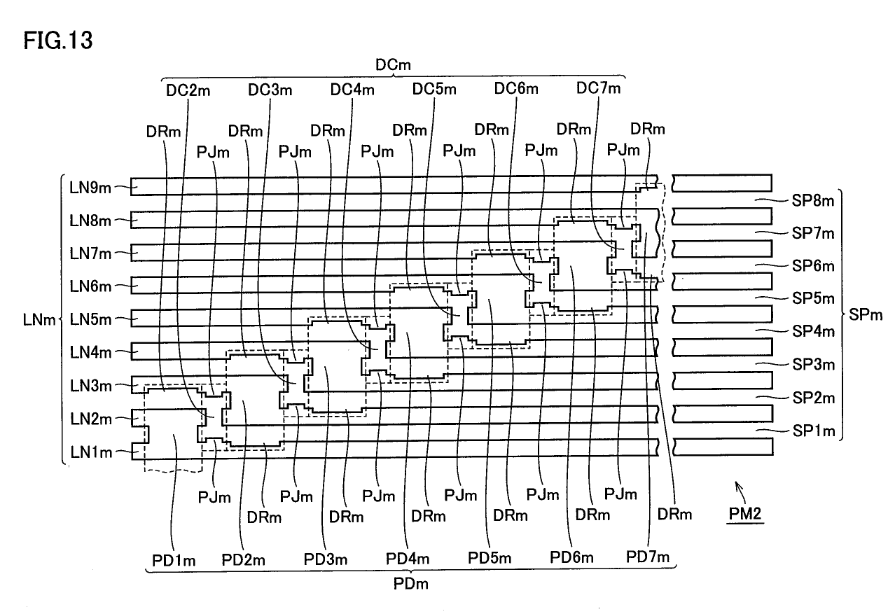

Referring to FIG. 13, in a photomask PM2 of the second embodiment, pad pattern PD3m is sandwiched between the set of line patterns LN2m and LN5m with the space pattern interposed therebetween. Each of line patterns LN2m and LN5m includes a recess DRm in a portion which faces pad pattern PD3m with the space pattern interposed therebetween.

Open-circuit portion DC3m is sandwiched between the set of line patterns LN2m and LN4m with the space pattern interposed therebetween. Each of line patterns LN2m and LN4m includes a protrusion PJm in a portion which faces open-circuit portion DC3m with the space pattern interposed therebetween.

Pad pattern PD3m sandwiched between the set of line patterns LN2m and LN5m is described above by way of example. Similarly recesses DRm are provided in other pad patterns PDm sandwiched between line patterns LNm and LNm.

Open-circuit portion DC3m sandwiched between the set of line patterns LN2m and LN4m is described above by way of example. Similarly protrusions PJm are provided in other open-circuit portion DCm sandwiched between line patterns LNm and LNm.

The interconnection pattern of the semiconductor device of the second embodiment obtained with the photomask will be described below.

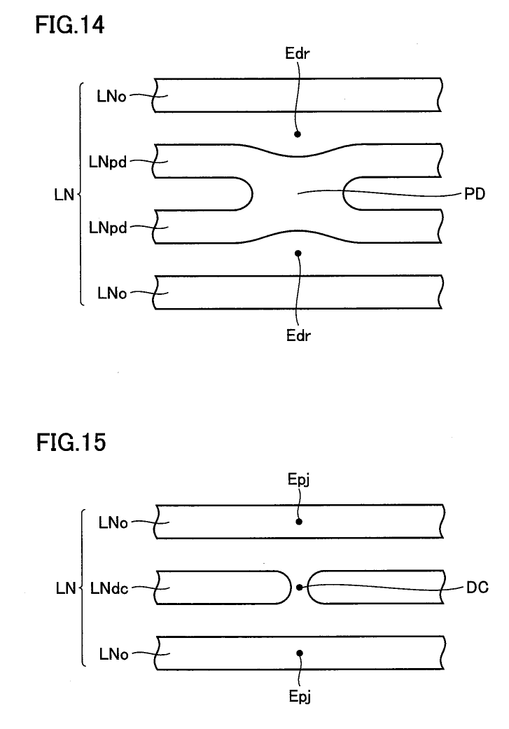

Mainly Referring to FIG. 14, because photomask PM2 has recess DRm, a tendency in which line widths of the set of line patterns LNo between which pad pattern PD is sandwiched is thickened toward a position Edr near pad pattern PD can be corrected to enhance evenness of the line width of line pattern LNo.

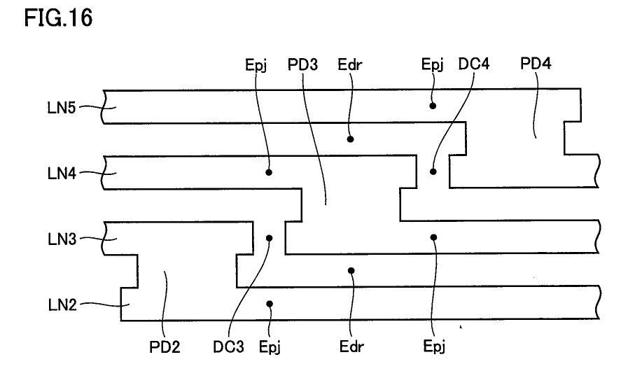

Mainly referring to FIG. 15, because photomask PM2 has above-described protrusion PJm, a tendency in which the set of line patterns LNo between which open-circuit portion DC is sandwiched is thinned in a position Epj near open-circuit portion DC can be corrected to enhance the evenness of the line width of line pattern LNo.

In the second embodiment, each of line patterns LN2m and LN5m of photomask PM2 (FIG. 13) has recess DRm in the portion which faces pad pattern PD3m with the space pattern interposed therebetween. Therefore, the evenness of the line widths of line patterns LN2 and LN5, between which pad pattern PD3 is sandwiched with the space pattern interposed therebetween, can be enhanced in the interconnection pattern (FIG. 16) of the semiconductor device which is produced with photomask PM2. Therefore, the enlargement of each line width of line patterns LN2 and LN5 can be prevented near pad pattern PD3, and the short circuit between pad pattern PD3 and position Edr can be prevented in line patterns LN2 and LN5.

Each of line patterns LN2m and LN4m of photomask PM2 (FIG. 13) has protrusion PJm in the portion which faces open-circuit portion DC3m with the space pattern interposed therebetween. Therefore, the evenness of the line widths of line patterns LN2 and LN4, between which open-circuit portion DC3 is sandwiched with the space pattern interposed therebetween, can be enhanced in the circuit pattern (FIG. 16) of the semiconductor device. Therefore, the open circuit of each line width of line patterns LN2 and LN4 can be prevented at position Epj near open-circuit portion DC3.

The optical proximity correction for the exposure process is performed to short-circuit pattern shape Sl (FIG. 4) and open-circuit pattern shape Dl (FIG. 5) whose areas are smaller than that of photomask pattern PM2 (FIG. 13). Therefore, the optical proximity correction can more simply be performed.

### Third Embodiment

A configuration of an interconnection pattern of a semiconductor device according to a third embodiment of the invention will be described.

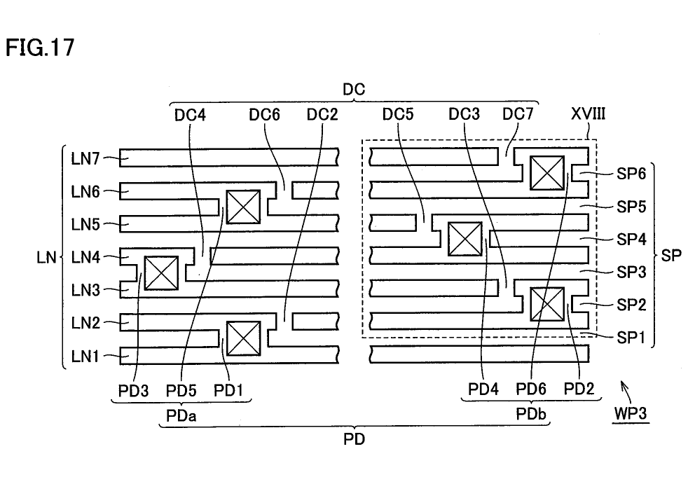

Referring to FIG. 17, an interconnection pattern WP3 of the third embodiment includes a plurality of line patterns LN (LN1 to LN7) and a plurality of pad patterns PD (PD1 to PD6). Line patterns LN are repeatedly disposed with space pattern SP (SP1 to SP6) interposed therebetween. Pad pattern PD is disposed while straddling a plurality of columns of line patterns LN. Each of line patterns LN2 to LN7 includes each (open-circuit portion DC) of open-circuit portions DC2 to DC7. In FIG. 17, the X-letter appended square located near the center of each pad pattern PD indicates the position of the contact hole made in pad pattern PD.

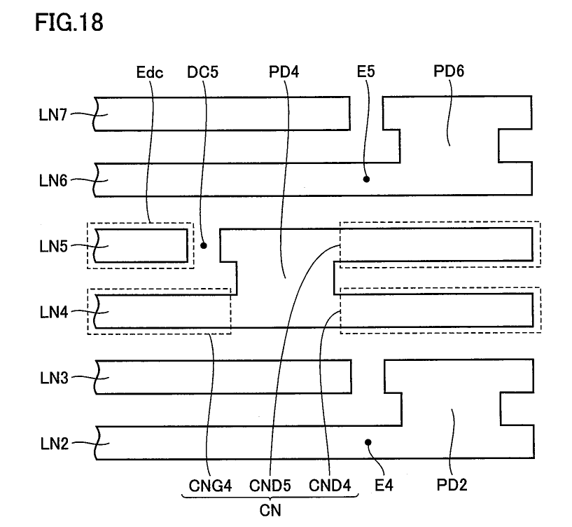

Referring to FIG. 18, pad pattern PD4 is disposed while straddling a plurality of columns of line patterns LN4 and LN5. In one (column of line pattern LN4) of the plurality of columns, pad pattern PD4 is connected to line pattern LN4 (interconnection CNG4) located on one side (left side in FIG. 18) of pad pattern PD4. In one (column of line pattern LN4) of the plurality of columns, pad pattern PD4 is connected to line pattern LN4 (interconnection CND4) located on the other side (right side in FIG. 18) of pad pattern PD4. In the other column (column of line pattern LN5) of the plurality of columns, pad pattern PD4 is connected to line pattern LN5 (interconnection CND5) located on the other side (right side in FIG. 18) of pad pattern PD4.

In pad pattern PD4 of the other column (column of line pattern LN5) of the plurality of columns, line pattern LN5 located on one side (left side in FIG. 18) of pad pattern PD4 includes open-circuit portion DC5.

Line patterns LN4 and LN5 connected to pad pattern PD4 and open-circuit portion DC5 included in line pattern LN5 are described above by way of example. As shown in FIG. 17, pad patterns PD2 and PD6 are also connected to line patterns LN, and the connected line pattern LN includes open-circuit portions DC. Because the relationship among pad patterns PD2 and PD6, line pattern LN, and open-circuit portion DC included in line pattern LN is similar to that of pad pattern PD4, the description is not given.

Referring to FIG. 17, pad patterns PD1, PD3, and PD5 are also connected to line pattern LN, and the connected line pattern LN includes open-circuit portion DC. The relationship among pad patterns PD1, PD3, and PD5, line pattern LN, and open-circuit portion DC included in line pattern LN is similar to the case in which the relationship between one side and the other side is replaced in pad patterns PD2, PD4, and PD6.

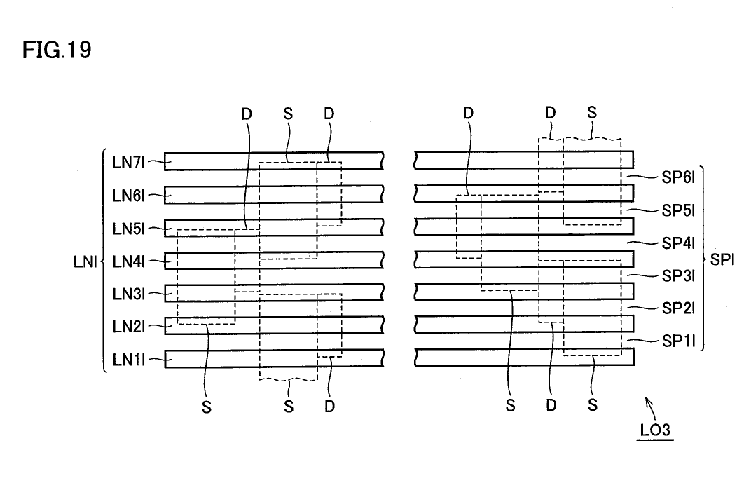

A pattern layout method for performing a pattern layout of a photomask of the third embodiment will be described. Mainly referring to FIG. 19, a basic pattern shape LO3 includes a plurality of line pattern shapes LN1 (LN1l to LN7l) which are repeatedly disposed with space pattern SP1 (SP1l to SP6l) interposed therebetween. A plurality of line pattern shapes LN1 have the same length, and line pattern shapes LN1 are arrayed along an L/S periodic direction.

Short-circuit region (one of regions) S and open-circuit region (the other region) D in basic pattern shape LO3 are replaced by a short-circuit pattern shape (first pattern shape) Sl (FIG. 4) and an open-circuit pattern shape (second pattern shape) Dl (FIG. 5) respectively. Therefore, the pattern layout of the photomask is performed.

Each broken-line portion corresponds to a region (short-circuit region S or open-circuit region D) where basic pattern shape LO3 are replaced in the pattern layout.

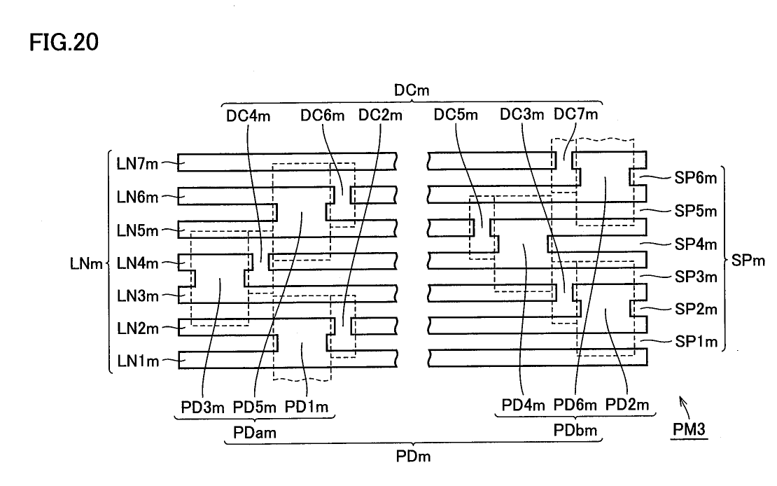

Referring to FIG. 20, a photomask PM3 of the third embodiment includes a plurality of line patterns LNm (LN1m to LN7m) and a plurality of pad patterns (straddling pattern) PDm (PD1m to PD6m). Line patterns LNm are repeatedly disposed with space pattern SPm (SP1m to SP6m) interposed therebetween. Pad pattern PDm is disposed while straddling a plurality of columns of line patterns LNm. Each of line patterns LN2m to LN7m includes each (open-circuit portion DCm) of open-circuit portions DC2m to DC7m.

For example, pad pattern PD4m is disposed while straddling a plurality of columns of line patterns LN4m and LN5m. In one (column of line pattern LN4m) of the plurality of columns, pad pattern PD4m is connected to line pattern LN4m located on one side (right side in FIG. 20) of pad pattern PD4m. In one (column of line pattern LN4m) of the plurality of columns, pad pattern PD4m is connected to line pattern LN4m located on the other side (right side in FIG. 20) of pad pattern PD4m. In the other column (column of line pattern LN5m) of the plurality of columns, pad pattern PD4m is connected to line pattern LN5m located on the other side (right side in FIG. 20) of pad pattern PD4m. In pad pattern PD4m of the other column (column of line pattern LN5m) of the plurality of columns, line pattern LN5m located on one side (left side in FIG. 20) of pad pattern PD4m includes open-circuit portion DC5m.

Line patterns LN4m and LN5m connected to pad pattern PD4m and open-circuit portions DC4m and DC5m included in line patterns LN4m and LN5m are described above by way of example. As shown in FIG. 20, pad patterns PD2m and PD6m are also connected to line patterns LNm, and the connected line pattern LNm includes open-circuit portions DCm. Because the relationship among pad patterns PD2m and PD6m, line pattern LNm, and open-circuit portion DCm included in line pattern LN is similar to that of pad pattern PD4m, the description thereof is not given.

Pad patterns PD1m, PD3m, and PD5m are also connected to line pattern LNm, and the connected line pattern LNm includes open-circuit portion DCm. The relationship among pad patterns PD1m, PD3m, and PD5m, line pattern LNm, and open-circuit portion DCm included in line pattern LNm is similarly established when the directions of one side and the other side are replaced in pad patterns PD2m, PD4m, and PD6m.

The semiconductor device having interconnection pattern WP3 (FIG. 17) is obtained with photomask PM3 by the production method similar to that of the first embodiment.

In the third embodiment, as shown in FIG. 18, interconnection CNG4 is connected to pad pattern PD4, so that interconnection CNG4 can be used such as the gate interconnection of the semiconductor device. For pad patterns PD2 and PD6, line pattern LN connected onto one side (right side in FIG. 18) of pad pattern PD can be used as the gate interconnection and the like. Referring to FIG. 17, for pad patterns PD1, PD3, and PD5, the references of one side and the other side are replaced by each other as described above, so that line pattern LN connected onto one side (right side in FIG. 17) of pad pattern PD can be used as the gate interconnection and the like.

Referring to FIGS. 17 and 18, pad pattern PD4 also straddles the column of line pattern LN5. However, pad patterns PD4 and an interconnection Edc PD5 connected to pad pattern PD5 are electrically separated from each other by the existence of open-circuit portion DC5. Therefore, the short circuit between pad patterns PD4 and PD5 can be prevented.

As shown in FIG. 18, pad pattern PD4 is connected to interconnection CND4 located on the other side (right side of FIG. 18) of the column of line pattern LN4. Therefore, interconnection CND4 is formed at a position shifted from a position E4 of line pattern LN2 by two columns. That is, the L/S regularity is enhanced in position E4 when compared to the absence of interconnection CND4. Therefore, the exposure process can more accurately be performed in position E4.

Pad pattern PD4 is also connected to interconnection CND5 located on the other side (right side of FIG. 18) of the column of line pattern LN5. Therefore, interconnection CND5 is formed at a position shifted from a position E5 of interconnection LN6 by one column. That is, the L/S regularity is enhanced in position E5 when compared to the absence of interconnection CND5. Therefore, the exposure process can more accurately be performed in position E5.

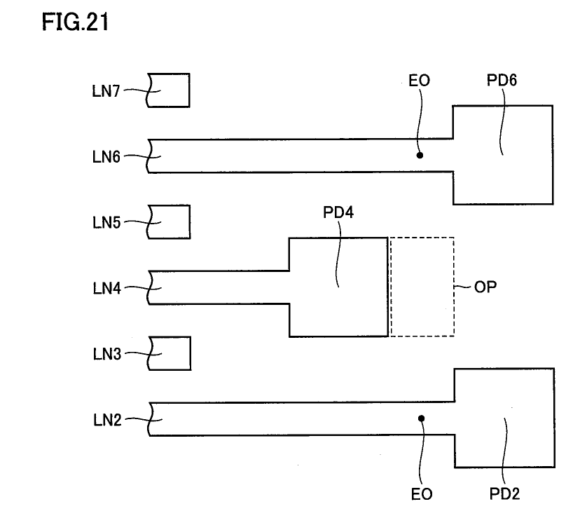

As shown in FIG. 21, in Comparative Example, contrary to the L/S regularity, region OP where the line pattern is not formed is enlarged on the other side (right side in FIG. 21) of pad pattern PD4. Accordingly, the accuracy of exposure process is lowered, and a possibility of opening positions E0 of line patterns LN2 and LN6 is enhanced contrary to the electric design of the semiconductor device.

### Fourth Embodiment

A pattern layout method for performing a pattern layout of a photomask used to produce a semiconductor device according to a fourth embodiment of the invention will be described.

Short-circuit region (one of regions) S and open-circuit region (the other region) in basic pattern shape LO3 (FIG. 19) are replaced by short-circuit pattern shape SO1 (FIG. 11) to which the optical proximity correction is already performed and open-circuit pattern shape DO1 (FIG. 12) to which the optical proximity correction is already performed respectively. Therefore, the pattern layout of the photomask is performed.

The photomask obtained by the pattern layout method will be described. Each of the broken-line portions corresponds to the region (short-circuit region S or open-circuit region D) where basic pattern shape LO3 (FIG. 19) is replaced in the pattern layout.

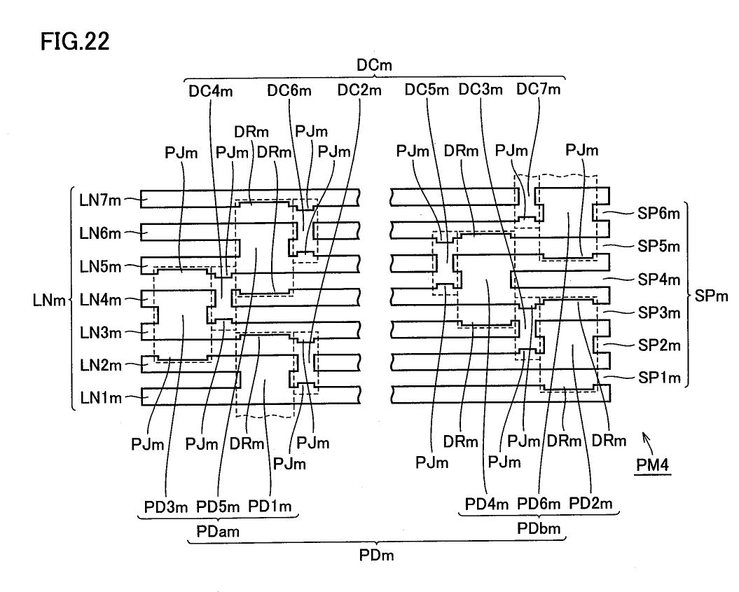

Referring to FIG. 22, similarly to the second embodiment, a photomask PM4 of the fourth embodiment includes recess DRm and protrusion PJm. That is, photomask PM4 includes recess DRm in the portion in which line pattern LNm faces pad pattern PDm with the space pattern interposed therebetween, and photomask PM4 includes protrusion PJm in the portion which faces open-circuit portion DCm with the space pattern interposed therebetween.

The semiconductor device having the interconnection pattern substantially similar to interconnection pattern WP3 (FIG. 17) of the third embodiment is obtained with photomask PM4 by the production method similar to that of the first embodiment.

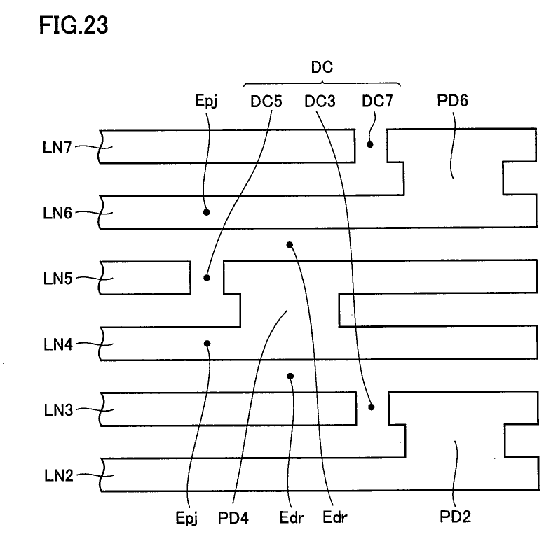

In the fourth embodiment, photomask PM4 (FIG. 22) includes recess DRm in the portion in which each of line patterns LN3m and LN6m faces pad pattern PD4m with the space pattern interposed therebetween. Therefore, the evenness of the line widths of line patterns LN3 and LN6, between which pad pattern PD4 is sandwiched while the space pattern is interposed between pad pattern PD4 and line patterns LN3 and LN6, can be enhanced in the interconnection pattern of the semiconductor device partially shown in FIG. 23. Accordingly, the enlargement of each line width of line patterns LN3 and LN6 is prevented near pad pattern PD4, so that the short circuit between pad pattern PD4 and position Edr can be prevented in each of line patterns LN3 and LN6.

Photomask PM4 (FIG. 22) includes protrusion PJm in the portion in which each of line patterns LN4m and LN6m faces open-circuit portion DC5m with the space pattern interposed therebetween. Therefore, the evenness of the line widths of line patterns LN4 and LN6, between which open-circuit portion DC5 is sandwiched while the space pattern is interposed between open-circuit portion DC5 and line patterns LN4 and LN6, can be enhanced in the interconnection pattern of the semiconductor device partially shown in FIG. 23. Accordingly, the open circuits of line patterns LN4 and LN6 can be prevented at position Epj near open-circuit portion DC5.

### Fifth Embodiment

A semiconductor device according to a fifth embodiment of the invention including a gate interconnection and a double-layer-structure metal interconnection will be described. The gate interconnection is provided on a semiconductor substrate, and the metal interconnection having the double layer structure is used to establish electrical contact with the gate interconnection.

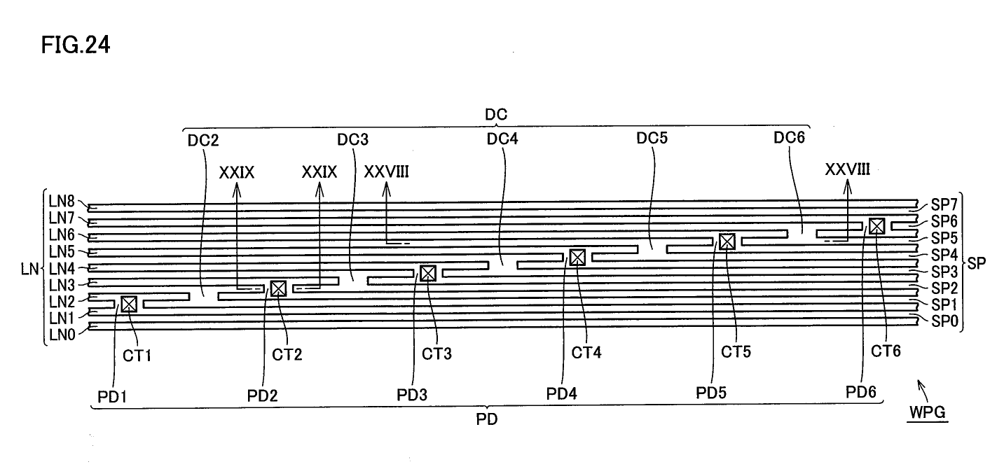

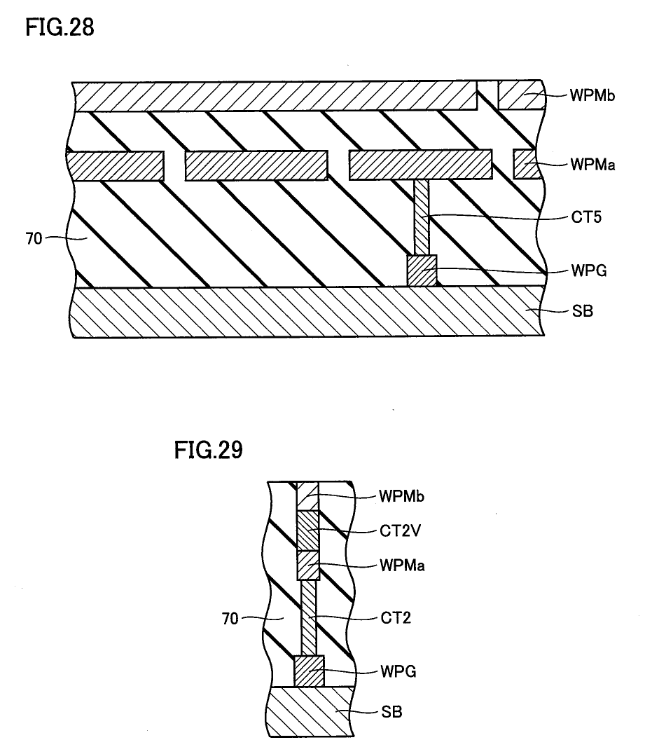

Mainly referring to FIG. 24, a gate interconnection WPG of the fifth embodiment is provided on a semiconductor substrate SB (FIGS. 28 and 29). Because gate interconnection WPG is substantially similar to interconnection pattern WP1 of the first embodiment, the identical or corresponding component is designated by the same numeral. Pad patterns PD (PD1 to PD7) are obliquely disposed relative to the L/S periodic direction, and Pad patterns PD are provided on the other side (left side in FIG. 3) in basic pattern shape LO1 (FIG. 3). Line pattern LN located on the other side (left side in FIG. 24) of pad pattern PD is a dummy interconnection.

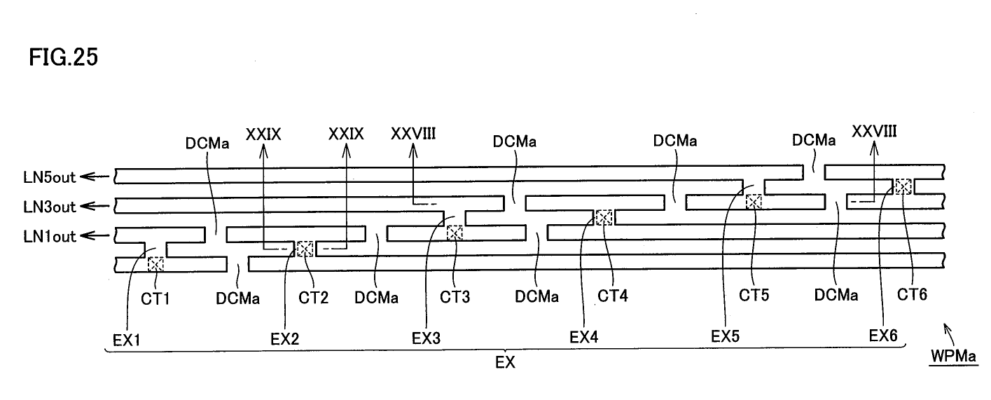

Referring to FIG. 25, a first metal interconnection WPMa of the fifth embodiment is provided on gate interconnection WPG with an insulating layer 70 (FIG. 28) interposed therebetween. Gate interconnection WPG and first metal interconnection WPMa are electrically connected through contact holes CT1 to CT6.

First metal interconnection WPMa includes L/S line patterns and pad patterns EX (EX1 to EX6). The line patterns are extended in the identical direction as gate interconnection WPG, and pad patterns EX (EX1 to EX6) straddle the plurality of line patterns. Open-circuit portions DCMa are provided in the line patterns of first metal interconnection WPMa.

An L/S pitch of first metal interconnection WPMa is set double an L/S pitch of gate interconnection WPG. In a plane layout, the line patterns of first metal interconnection WPMa are provided so as to pass over contact holes CT1, CT3, and CT5.

In pad patterns EX1, EX3, and EX5 and open-circuit portion DCMa, electric paths passing through contact holes CT1, CT3, and CT5 are drawn out to the other side (left side in FIG. 25) of first metal interconnection WPMa like LN1out, LN3out, and LN5out in FIG. 25, and the electric paths are provided so as not to make a short circuit with other electric paths passing through other contact holes. Each of pad patterns EX2 and EX4 is provided so as to straddle line patterns adjacent to each other on each of the contact holes CT2 and CT4.

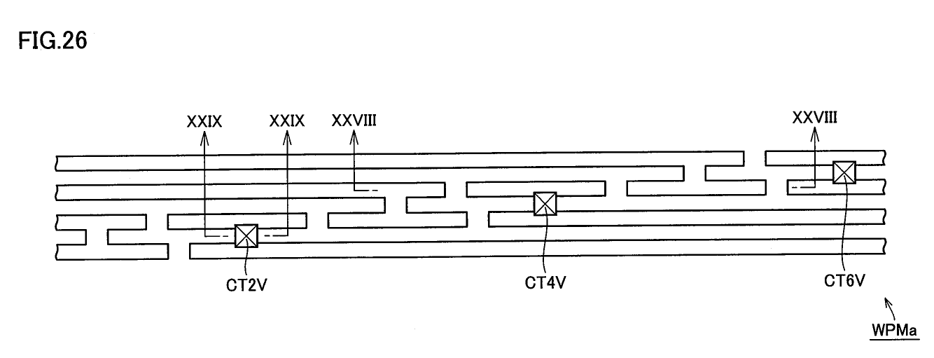

Mainly referring to FIGS. 25 and 26, via holes CT2V, CT4V, and CT6V made in insulating layer 70 (FIG. 28) are disposed on pad patterns EX2, EX4, and EX6 respectively.

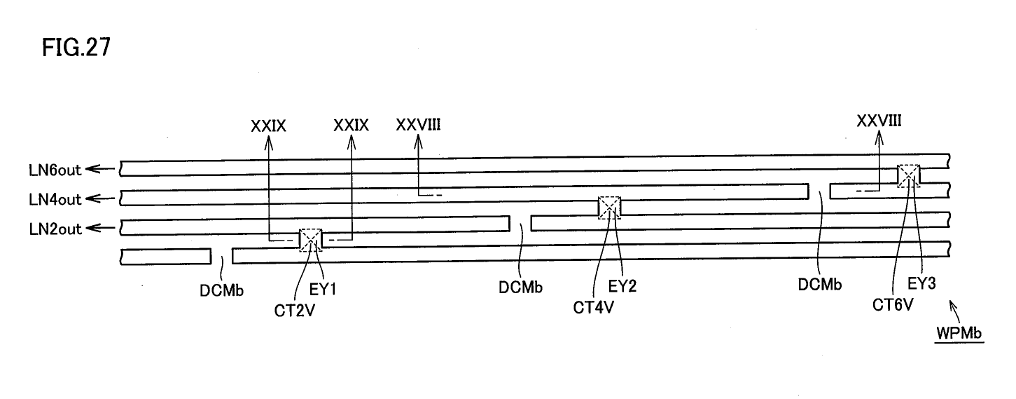

Referring to FIG. 27, a second metal interconnection WPMb of the fifth embodiment is provided on first metal interconnection WPMa with insulating layer 70 (FIG. 28) interposed therebetween. First metal interconnection WPMa and second metal interconnection WPMb are electrically connected through via holes CT2V, CT4V, and CT6V.

Second metal interconnection WPMb includes a basic pattern shape having L/S similar to that of first metal interconnection WPMa. Second metal interconnection WPMb includes the line pattern having the above-described L/S and pad patterns EY1 to EY3 straddling a plurality of line patterns. Open-circuit portions DCMb are provided in the line patterns of second metal interconnection WPMb.

In pad patterns EY1 to EY3 and open-circuit portion DCMb, electric paths passing through contact holes CT2, CT4, and CT6 are drawn out to the other side (left side in FIG. 27) of first metal interconnection WPMa like LN2out, LN4out, and LN6out in FIG. 27, and the electric paths are provided so as not to make the short circuit with other electric paths passing through other contact holes.

In the fifth embodiment, pad pattern PD (FIG. 24) is provided on the other side (left side in FIG. 3) in basic pattern shape LO1 (FIG. 3). Therefore, the length of the dummy interconnection which is of line pattern LN on the other side of the pad pattern PD is shortened in gate interconnections WPG, so that a wider portion of gate interconnection WPG can substantially be used.

Because the pad pattern in each of the first to fifth embodiments has the width larger than the line pattern, the contact hole can easily be made on the pad pattern. However, in the invention, it is not always necessary that the contact hole be made on the pad pattern. For example, only the pad pattern can be used to connect the line patterns adjacent to each other.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A semiconductor device comprising:
a plurality of line patterns which are repeatedly disposed with a space pattern interposed therebetween; and
a straddling pattern which straddles a plurality of columns of said plurality of line patterns, said straddling pattern being connected to said plurality of line patterns in one of said plurality of columns on one side of said straddling pattern, said straddling pattern being connected to said plurality of line patterns in another column of said plurality of columns on the other side of said straddling pattern, said plurality of line patterns including an open-circuit portion in said another column on said one side.

2. The semiconductor device according to claim 1, wherein said plurality of line patterns include an open-circuit portion in said one of said plurality of columns on said other side.

3. The semiconductor device according to claim 1, wherein said plurality of line patterns have a dummy line in said another column on said other side.

4. A photomask comprising:
a plurality of line patterns which are repeatedly disposed with a space pattern interposed therebetween; and
a straddling pattern which straddles a plurality of columns of said plurality of line patterns, said straddling pattern being connected to said plurality of line patterns in one of said plurality of columns on one side of said straddling pattern, said straddling pattern being connected to said plurality of line patterns in another column of said plurality of columns on the other side of said straddling pattern, said plurality of line patterns including an open-circuit portion in said another column on said one side.

5. The photomask according to claim 4, wherein said plurality of line patterns include an open-circuit portion in said one of said plurality of columns on said other side.

6. The photomask according to claim 4, wherein said plurality of line patterns include a recess in a portion which faces said straddling pattern with said space pattern interposed therebetween.

7. The photomask according to claim 4, wherein said plurality of line patterns include a protrusion in a portion which faces said open-circuit portion with said space pattern interposed therebetween.

8. A semiconductor device production method in which the photomask according to claim 4 is used, the method comprising the steps of:
applying a photoresist onto a semiconductor substrate; and
exposing said photoresist with off axis illumination using said photomask.

9. A pattern layout method for performing a pattern layout of a photomask, the method comprising the steps of:
performing optical proximity correction to a first pattern shape, said first pattern shape including a plurality of line pattern shapes which run parallel to one another with a space pattern interposed therebetween, a pattern shape which straddles said plurality of line pattern shapes, and a set of line pattern shapes which runs parallel to said plurality of line pattern shapes, said straddling pattern shape being sandwiched between said set of line pattern shapes with a space pattern interposed therebetween;
performing optical proximity correction to a second pattern shape, said second pattern shape including a line pattern shape which has an open-circuit portion and a set of line pattern shapes which runs parallel to said line pattern shapes having said open-circuit portion, said open-circuit portion being sandwiched between said set of line pattern shapes with a space pattern interposed therebetween; and
replacing respectively one of regions and another region in a pattern shape by said first and second pattern shapes to which said optical proximity correction is already performed, said pattern shape including a plurality of line pattern shapes which are repeatedly disposed with a space pattern interposed therebetween.
